(19) United States
(12) Patent Application Publication
(10) Pub. No.: US 2012/0273799 A1
(43) Pub. Date: Nov. 1, 2012

(54) SEMICONDUCTOR DEVICE AND FABRICATION METHOD FOR THE SAME

(75) Inventor: Kazutaka Takagi, Kawasaki-shi (JP)

(73) Assignee: KABUSHIKI KAISHA TOSHIBA, Tokyo (JP)

(21) Appl. No.: 13/311,127

(22) Filed: Dec. 5, 2011

(30) Foreign Application Priority Data
Apr. 28, 2011 (JP) 2011-101271

(51) Int. Cl. H01L 23/48; H01L 21/50; H01L 23/498

(52) U.S. Cl. 257/77; 257/741; 257/76; 257/774; 438/118; 257/E23.067; 257/E23.01; 257/E21.499

(57) ABSTRACT

According to an embodiment, a semiconductor device includes: a conductive base plate; a semiconductor chip bonded on the conductive base plate, a first adhesive agent disposed on a central part of a bonded surface between the semiconductor chip and the conductive base plate; and a second adhesive agent disposed on a peripheral part of the central part of the bonded surface between the semiconductor chip and the conductive base plate. A coefficient of thermal conductivity of the first adhesive agent is relatively higher than that of the second adhesive agent, and a bonding strength of the second adhesive agent is relatively higher than that of the first adhesive agent.

### CROSS REFERENCE TO RELATED APPLICATIONS

This application is based upon and claims the benefit of priority from prior Japanese Patent Application No. P2011-101271 filed on Apr. 28, 2011, the entire contents of which are incorporated herein by reference.

### FIELD

Embodiment described herein generally relates to a semiconductor device and a fabrication method for such semiconductor device.

### BACKGROUND

Conventionally, there is a method for achieving miniaturization of a microwave semiconductor device using a Monolithic Microwave Integrated Circuit (MMIC), for example. In such the MMIC, an MMIC substrate is bonded on a conductive base plate using an adhesive agent, such as an adhesive agent having electrical conductivity and thermal conductivity.

As an adhesive agent for bonding a semiconductor chip on a conductive base plate, an epoxy based adhesive agent composed of organic materials, such as an epoxy resin, including Ag as a conductive filler has a high coefficient of thermal conductivity. However, the epoxy based adhesive agent is hardened after performing cure treatment. Therefore, when the epoxy based adhesive agent is used for bonding a large-sized semiconductor chip on a conductive base plate, the large-sized semiconductor chip is easy to be removed from the conductive base plate due to a difference of linear thermal expansion at the time of the cure treatment between the semiconductor chip and the conductive base plate.

On the other hand, a polyester based adhesive agent composed of polyester based polymeric materials including Ag as a conductive filler is flexible also after the cure treatment. Therefore, even when the polyester based adhesive agent is used for bonding a large-sized semiconductor chip on a conductive base plate, the large-sized semiconductor chip is hard to remove from the conductive base plate even if a difference of linear thermal expansion at the time of cure treatment between the semiconductor chip and the conductive base plate is large. However, since the polyester based adhesive agent has a low density to include Ag, the polyester based adhesive agent has a low degree of coefficient of thermal conductivity and inferior thermal dispersion characteristics.

An epoxy and polyester mixed based adhesive agent having intermediate characteristics between the epoxy based adhesive agent and the polyester based adhesive agent can improve the disadvantage of both of the epoxy based adhesive agent and the polyester based adhesive agent. However, according to the epoxy and polyester mixed based adhesive agent, the advantage of both of the epoxy based adhesive agent and the polyester based adhesive agent is undermined.

### BRIEF DESCRIPTION OF THE DRAWINGS

FIG. 1A shows a semiconductor device according to an embodiment, and is a schematic bird's-eye view in the case of applying MMIC as a semiconductor chip.

FIG. 1B is a schematic cross-sectional configuration diagram taken in the line I-I of FIG. 1A.

FIG. 2A is a schematic plan view corresponding to FIG. 1A.

FIG. 2B is a schematic cross-sectional configuration diagram taken in the line II-II of FIG. 2A.

FIG. 3A shows a semiconductor device according to a modified example 1 of the embodiment, and is a schematic plan view in the case of applying FET as a semiconductor chip.

FIG. 3B is a schematic cross-sectional configuration diagram taken in the line line of FIG. 3A.

FIG. 4 is a schematic cross-sectional configuration diagram taken in the line IV-IV line of FIG. 3A.

FIG. 5A is a schematic diagram showing an example of a coating variation between a first adhesive agent and a second adhesive agent in the semiconductor device according to the embodiment, and shows an aspect that the first adhesive agent is coated while forming apertures at four corners of the second adhesive agent.

FIG. 5B is a schematic diagram showing an aspect that the first adhesive agent is coated while forming apertures at two corners of the second adhesive agent.

FIG. 5C is a schematic diagram showing an aspect that the first adhesive agent is coated while forming apertures at one corner of the second adhesive agent.

FIG. 5D is a schematic diagram showing an aspect that the first adhesive agent is coated while forming apertures at one side of the second adhesive agent.

FIG. 6 is a schematic diagram showing a difference of displacement Δ in the case where the semiconductor chip is displaced to the point P at the distance x from the center (point O) of a bonded surface due to a difference of coefficient of linear thermal expansion ΔCTE (1/k) of the semiconductor chip to a conductive base plate, after the semiconductor chip is subjected to the cure treatment at 200 degrees C. and then is cooled to room temperature.

FIG. 7 is a graphic chart showing a correlation between the upper limit of the size of the semiconductor chip (longitudinal distance L (μm)) and the difference of coefficient of linear thermal expansion ΔCTE (1/k) between the semiconductor chip and the conductive base plate.

FIG. 8 is a graphic chart showing a correlation between the cure treatment time and the cure treatment temperature of the first adhesive agent and the second adhesive agent used for bonding a bonded surface between the semiconductor chip and the conductive base plate, in the semiconductor device according to the embodiment.

FIG. 9 is another graphic chart showing a correlation between the cure treatment time and the cure treatment temperature of the first adhesive agent and the second adhesive agent used for bonding a bonded surface between the semiconductor chip and the conductive base plate, in the semiconductor device according to the embodiment.

FIG. 10 is a graph chart showing a correlation between: the distance x (mm) from the center of the bonded surface between the semiconductor chip (SiC) and the conductive base plate (Cu); and a value of displacement Δx (μm) and a difference of displacement value Δ (μm); after the semiconductor chip is subjected to the cure treatment at 200 degrees C. and then is cooled to room temperature, in the semiconductor device according to the embodiment.

FIG. 11 is a schematic planar pattern configuration diagram showing an example of mounting of the semiconductor chip and others parts, in the semiconductor device according to the embodiment.

FIG. 12 is a schematic cross-sectional configuration diagram taken in the line VI-VI of FIG. 11.

FIG. 13A is an enlarged drawing showing a schematic planar pattern configuration of a semiconductor chip mounted in the semiconductor device according to the embodiment.

FIG. 13B is an enlarged drawing showing a portion J of FIG. 13A.

FIG. 14 is a constructional example 1 of the semiconductor chip mounted in the semiconductor device according to the embodiment, and is a schematic cross-sectional configuration diagram taken in the line VII-VII of FIG. 13B.

FIG. 15 is a constructional example 2 of the semiconductor chip mounted in the semiconductor device according to the embodiment, and is a schematic cross-sectional configuration diagram taken in the line VII-VII of FIG. 13B.

FIG. 16 is a constructional example 3 of the semiconductor chip mounted in the semiconductor device according to the embodiment, and is a schematic cross-sectional configuration diagram taken in the line VII-VII of FIG. 13B.

FIG. 17 is a constructional example 4 of the semiconductor chip mounted in the semiconductor device according to the embodiment, and is a schematic cross-sectional configuration diagram taken in the line VII-VII of FIG. 13B.

FIG. 18 is a schematic planar pattern configuration diagram showing an alternative constitution of the semiconductor chip mounted in the semiconductor device according to the embodiment.

### DETAILED DESCRIPTION

Hereinafter, embodiments will be described with reference to drawings.

According to one embodiment, a semiconductor device includes a conductive base plate, a semiconductor chip, a first adhesive agent, and a second adhesive agent. The semiconductor chip is bonded on the conductive base plate. The first adhesive agent is disposed on a central part of a bonded surface between the semiconductor chip and the conductive base plate. The second adhesive agent is disposed on a peripheral part of the bonded surface between the semiconductor chip and the conductive base plate. In this case, a coefficient of thermal conductivity of the first adhesive agent is relatively higher than that of the second adhesive agent, and a bonding strength of the second adhesive agent is relatively higher than that of the first adhesive agent.

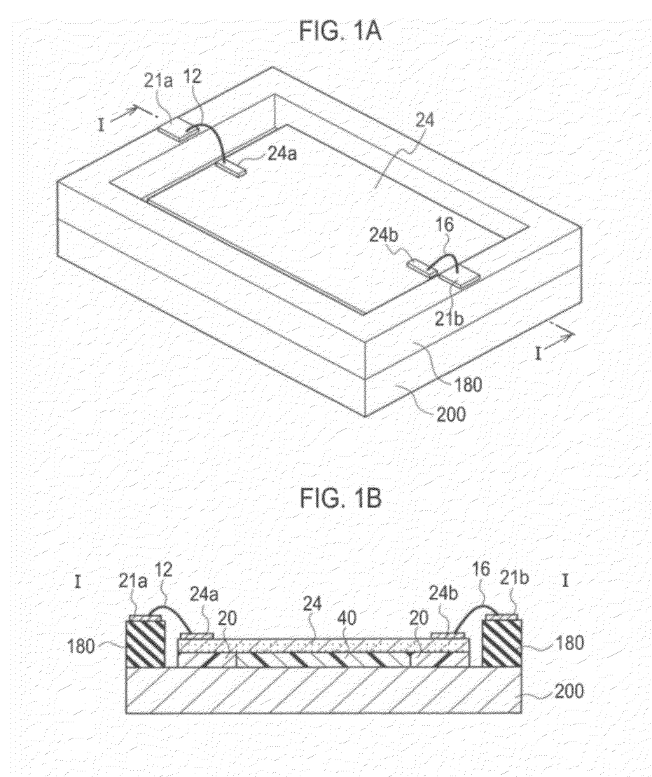

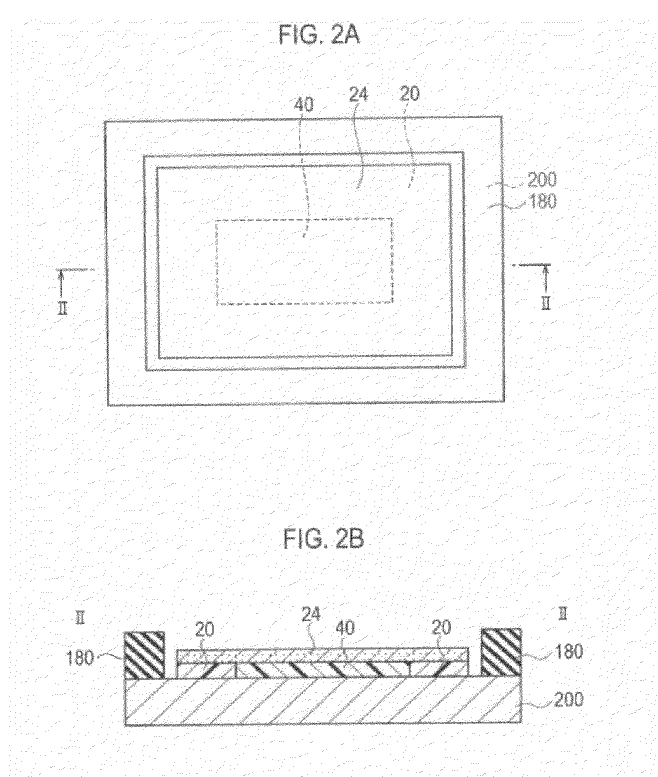

A diagram showing the semiconductor device according to the embodiment, and showing a schematic bird's-eye view structure in the case of applying MMIC as a semiconductor chip 24 is expressed as shown in FIG. 1A. A schematic cross-sectional structure taken in the line I-I of FIG. 1A is expressed as shown in FIG. 1B. Also, a schematic plan view corresponding to FIG. 1A is expressed as shown in FIG. 2A, and a schematic cross-sectional structure taken in the line II-II of FIG. 2A is expressed as shown in FIG. 2B.

The semiconductor device according to the embodiment includes: a conductive base plate 200; a semiconductor chip 24 bonded on the conductive base plate 200; a first adhesive agent 40 disposed on a central part of a bonded surface between the semiconductor chip 24 and the conductive base plate 200; and a second adhesive agent 20 disposed on a peripheral part of the central part of the bonded surface between the semiconductor chip 24 and the conductive base plate 200. In this case, the first adhesive agent 40 has a coefficient of thermal conductivity relatively higher than that of the second adhesive agent 20, and the second adhesive agent 20 has a bonding strength relatively higher than that of the first adhesive agent 40.

On the other hand, a fabrication method for the semiconductor device according to the embodiment includes: forming the first adhesive agent 40 on the central part of the bonded surface between the semiconductor chip 24 and the conductive base plate 200; forming the second adhesive agent 20 on the peripheral part of the central part of the bonded surface between the semiconductor chip 24 and the conductive base plate 200; mounting the semiconductor chip 24 on the first adhesive agent 40 and the second adhesive agent 20 on the conductive base plate 200; and subjecting the first adhesive agent 40 and the second adhesive agent 20 to a cure treatment to be hardened.

More specifically, a semiconductor device according to the embodiment includes: the conductive base plate 200; the semiconductor chip 24 (e.g., MMIC substrate) having an input terminal 24a and an output terminal 24b, and bonded on the conductive base plate 200; a ceramic frame 180 disposed on the conductive base plate 200 to surround the semiconductor chip 24; an RF input terminal 21a and an RF output terminal 21b disposed on the ceramic frame 180; a bonding wire 12 for connecting between the RF input terminal 21a and the input terminals 24a; and a bonding wire 16 for connecting between the output terminal 24b and the RF output terminals 21b.

The semiconductor chip 24 is bonded on the conductive base plate 200 by the first adhesive agent 40 and the second adhesive agent 20. The first adhesive agent 40 is an adhesive agent for bonding the central part of the bonded surface between the semiconductor chip 24 and the conductive base plate 200. An adhesive agent having a coefficient of thermal conductivity relatively higher than that of the second adhesive agent 20 (e.g., an epoxy based adhesive agent composed of organic materials, such as an epoxy resin, including Ag as a conductive filler) is applicable to the first adhesive agent 40. The second adhesive agent 20 is an adhesive agent for bonding the peripheral part of the central part of the bonded surface of the semiconductor chip 24 and the conductive base plate 200 (i.e., peripheral part of the central part bonded by the first adhesive agent 40). An adhesive agent having a bonding strength higher than that of the first adhesive agent 40 (e.g. , a polyester based adhesive agent composed of polyester based polymeric materials including Ag as a conductive filler) is applicable to the second adhesive agent 20.

The first adhesive agent 40 has an advantage that a coefficient of thermal conductivity of the first adhesive agent 40 is high. However, the first adhesive agent 40 is easy to harden after the cure treatment. Therefore, the first adhesive agent 40 also has a disadvantage that the semiconductor chip is removed from the conductive base plate 200 easily by a thermal contraction due to a difference of linear thermal expansion between the semiconductor chip 24 and the conductive base plate 200 at the time of the cure treatment, when the first adhesive agent 40 is used for bonding of the large-sized semiconductor chip 24. On the other hand, the second adhesive agent 20 is flexible even after the cure treatment. Therefore, the second adhesive agent 20 has an advantage that the semiconductor chip is hard to remove from the conductive base plate 200, even when the second adhesive agent 20 is used for bonding of the large-sized semiconductor chip 24 with the large difference of linear thermal expansion between the semiconductor chip 24 and the conductive base plate 200 at the time of the cure treatment. However, since the second adhesive agent 20 has a low density to include Ag, there also is a disadvantage that the second adhesive agent 20 has low coefficient of thermal conductivity and inferior thermal dispersion characteristics.

Furthermore, in the central part of the bonded surface between the semiconductor chip 24 and the conductive base plate 200, there are characteristics that the difference of displacement of the heat contraction due to the difference of linear thermal expansion between the semiconductor chip 24 and the conductive base plate 200 is small, although the calorific value is large. On the other hand, in the peripheral part of the central part of the bonded surface between the semiconductor chip 24 and the conductive base plate 200, there are characteristics that calorific value is small, although the difference of displacement of the heat contraction due to the difference of linear thermal expansion between the semiconductor chip 24 and the conductive base plate 200 is large.

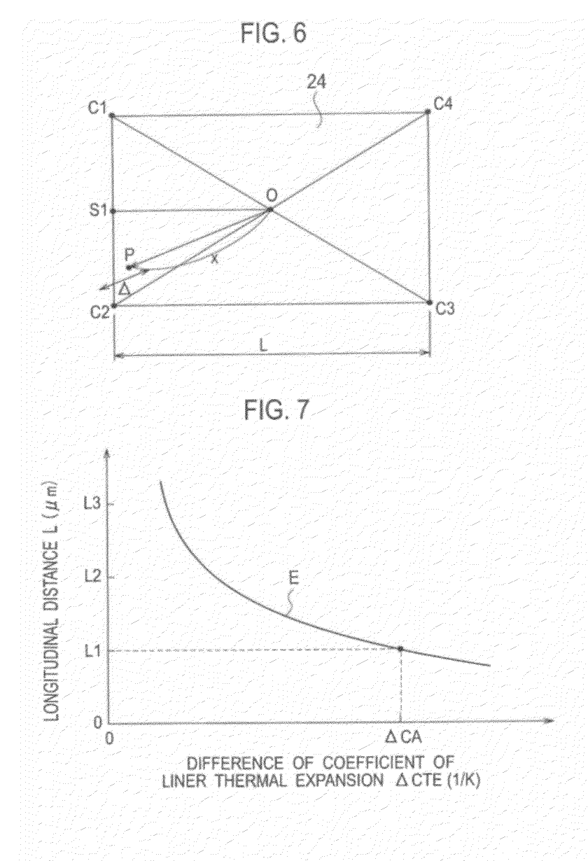

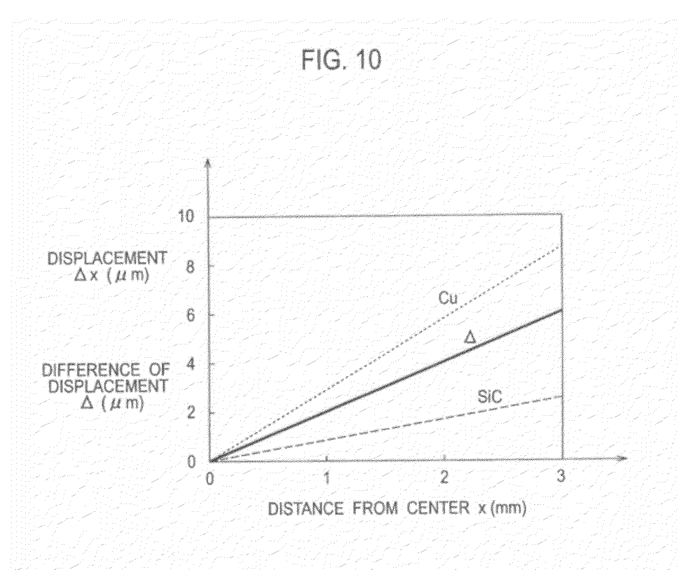

More specifically, as shown in FIG. 6, FIG. 7, and FIG. 10, the difference of displacement Δ of the heat contraction due to the difference of linear thermal expansion between the semiconductor chip 24 and the conductive base plate 200 is dependent on the distance x from the central point (O) of the bonded surface of the semiconductor chip 24 acting as a bonded surface with the conductive base plate 200, and the difference of coefficient of linear thermal expansion ΔCTE [1/k] between the semiconductor chip 24, and the conductive base plate 200. That is, the value of displacement Δx and the difference of displacement Δ is zero at the central point (O) of the bonded surface even when the thermal contraction occurs, and the value of displacement Δx and the difference of displacement Δ also increases in proportion as the distance x from the central point (O) becomes large.

In addition, FIG. 6 shows an example of the difference of displacement Δ in the case where the semiconductor chip 24 (longitudinal distance L [μm]), after the semiconductor chip 24 and the conductive base plate 200 are bonded, subjected to the cure treatment at 200 degrees C. and then cooled to room temperature, is displaced to the point P at the distance x from the center (O) of the bonded surface due to the difference of coefficient of linear thermal expansion ΔCTE [1/k] with the conductive base plate.

Moreover, FIG. 7 shows an example of the correlation between the upper limit of the size of the semiconductor chip (longitudinal distance L (μm)) and the difference of coefficient of linear thermal expansion ΔCTE [1/k] between the semiconductor chip 24 and the conductive base plate 200, in the case where the semiconductor chip 24 and the conductive base plate 200 are bonded by the epoxy based adhesive agent. For example, when the difference of coefficient of linear thermal expansion ΔCTE between the semiconductor chip 24 and the conductive base plate 200 is ΔCA [1/k], the upper limit of the size (longitudinal distance L) is L1 [μm]. As clearly from FIG. 7, it becomes impossible to mount only the semiconductor chip 24 whose longitudinal distance L is small, in proportion as the difference of coefficient of linear thermal expansion ΔCTE between the semiconductor chip 24 and the conductive base plate 200 becomes large. On the other hand, it becomes possible to gradually mount also the semiconductor chip 24 whose longitudinal distance L is more large (longitudinal distance L=L1<L2<L3), in proportion as the difference of coefficient of linear thermal expansion ΔCTE between the semiconductor chip 24 and the conductive base plate 200 becomes small.

Moreover, FIG. 10 shows an example of the correlation between the distance x [mm] from the center of the bonded surface between the semiconductor chip 24 and the conductive base plate 200, and the value of displacement Δx [μm] and the difference of displacement value Δ [μm], in the case where the semiconductor chip 24 and the conductive base plate 200 are bonded, subjected to the cure treatment at 200 degrees C. and cooled to the room temperature. In the graphic chart shown in FIG. 10, Cu denotes the value of displacement Δx of the copper conductive base plates 200, SiC denotes the value of displacement Δx of the semiconductor chip 24 composed of the SiC substrate, and Δ denotes the difference of displacement value Δ between the conductive base plate 200 and the semiconductor chip 24. In addition, the graphic chart shown in FIG. 10 shows an example of each value calculated from the case where the coefficient of linear thermal expansion CTE of the conductive base plate (Cu) 200 is set to 17×10⁻⁶ [1/K] and the coefficient of linear thermal expansion CTE of the semiconductor chip (SiC) 24 is set to 5×10⁻⁶ [1/K].

Accordingly, in the semiconductor device according to the embodiment, the first adhesive agent 40 having the coefficient of thermal conductivity relatively higher than that of the second adhesive agent 20 is used for bonding the central part (i.e., the region where the difference of displacement of the heat contraction due to the difference of linear thermal expansion between the semiconductor chip 24 and the conductive base plate 200 is small although the calorific value is large, compared with that of the peripheral part) of the bonded surface between the semiconductor chip 24 and the conductive base plate 200. Also, the second adhesive agent 20 having the bonding strength relatively higher than that of the first adhesive agent 40 is used for bonding the peripheral part (i.e., the region where the calorific value is small although the difference of displacement of the heat contraction due to the difference of linear thermal expansion between the semiconductor chip 24 and the conductive base plate 200 is large, compared with the central part) of the central part of the bonded surface between the semiconductor chip 24 and the conductive base plate 200. Accordingly, the disadvantage of the first adhesive agent 40 (i.e., the upper limit of the size of the semiconductor chip 24 (longitudinal distance L (μm)) is small, compared with the second adhesive agent 20) and the disadvantage of the second adhesive agent 20 (i.e., the thermal dispersion characteristics is inferior because of low coefficient of thermal conductivity compared with the first adhesive agent 40) can be far outweighed mutually, without impairing both of the advantage of the first adhesive agent 40 (i.e., the thermal dispersion characteristics is excellent because of high coefficient of thermal conductivity compared with the second adhesive agent 20) and the advantage of the second adhesive agent 20 (i.e., the endurance is excellent because of high bonding strength compared with the first adhesive agent 40).

Therefore, according to the embodiment, since the semiconductor device has the structure for bonding by using different adhesive agents (i.e., the adhesive agent excellent in the thermal dispersion characteristics and the adhesive agent excellent in the bonding strength) properly, it can achieve the semiconductor device excellent in the thermal dispersion characteristics and the bonding strength.

Generally, the temperature during mounting process using AuSn solder is about 300 degrees C. On the other hand, according to the semiconductor device according to the embodiment, the temperature during mounting process can be reduced to about 150 to about 250 degrees C. by bonding using the first adhesive agent and the second adhesive agent 20. Accordingly, the semiconductor device according to the embodiment can be applied to a thin type package for millimeter wave use, and can be applied to not only a thin package but also a comparatively inexpensive package.

### (Correlation Between Cure Time and Cure Temperature)

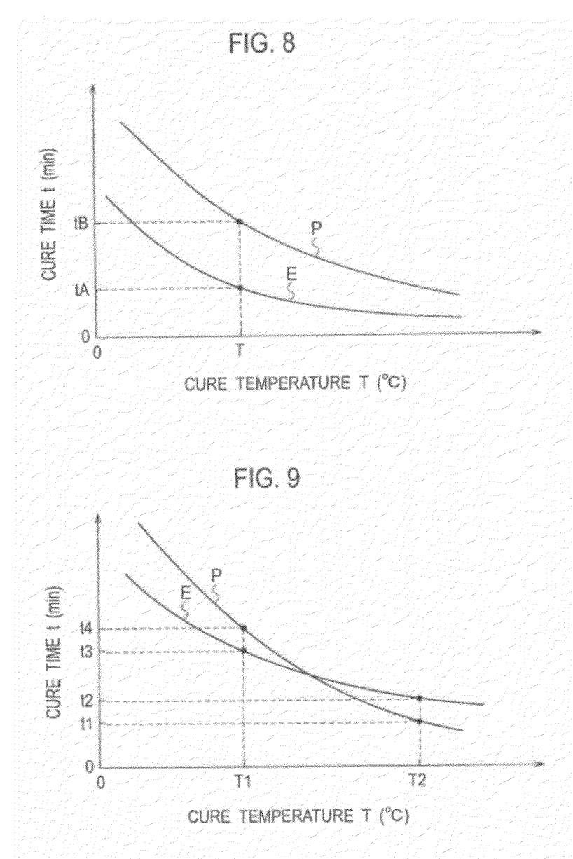

FIG. 8 is a graphic chart showing the correlation between the cure treatment time and the cure treatment temperature of the first adhesive agent and the second adhesive agent used for bonding the bonded surface between the semiconductor chip and the conductive base plate, in the semiconductor device according to the embodiment.

FIG. 8 shows the correlation between the cure treatment time and cure treatment temperature of the epoxy based adhesive agent (E) and the polyester based adhesive agent (P) used for bonding the bonded surface between the semiconductor chip 24 and the conductive base plate 200, in the semiconductor device according to the embodiment. For example, when the cure temperature is T, the cure treatment time of the polyester based adhesive agent (P) is tB, and the cure treatment time of the epoxy based adhesive agent (E) is tA. That is, as clearly from FIG. 8, at the cure temperature T, the period of the cure treatment time of the polyester based adhesive agent (P) is Δ(tB−tA) longer than the period of the cure treatment time of the epoxy based adhesive agent (E). In FIG. 8, the state where the period of the cure treatment time of the polyester based adhesive agent (P) has exceeded rather than the period of the cure treatment time of the epoxy based adhesive agent (E) continues in all over the cure temperature T. Therefore, in the semiconductor device according to the embodiment, the amount of the cure treatment time of epoxy based adhesive agent (E) is not longer rather than that of the cure treatment time of polyester based adhesive agent (P) even when changing the temperature conditions. If such the epoxy based adhesive agent (E) and the polyester based adhesive agent (P) are selected respectively as the first adhesive agent 40 and the second adhesive agent 20, the central part of the bonded surface between the semiconductor chip 24 and the conductive base plate 200 is bonded by the first adhesive agent 40, and the peripheral part of the bonded surface is bonded by the second adhesive agent 20, the second adhesive agent 20 coated on the outside of the bonded surface hardens before the first adhesive agent 40 coated on the inside of the bonded surface hardens. As a result, it becomes impossible to volatilize volatile gas occurred when the first adhesive agent 40 coated on the inside of the bonded surface hardens.

On the other hand, FIG. 9 is another graphic chart showing a correlation between the cure treatment time and the cure treatment temperature of the first adhesive agent and the second adhesive agent used for bonding the bonded surface between the semiconductor chip and the conductive base plate, in the semiconductor device according to the embodiment.

FIG. 9 is another graphic chart showing another correlation between the cure treatment time and the cure treatment temperature of the epoxy based adhesive agent (E) and the polyester based adhesive agent (P) used for bonding the bonded surface between the semiconductor chip 24 and the conductive base plate 200, in the semiconductor device according to the embodiment. More specifically, FIG. 9 shows a temperature span where the period of the cure treatment time of the polyester based adhesive agent (P) is longer than the period of the cure treatment time of an epoxy based adhesive agent (E), and a temperature span where the period of the cure treatment time of the polyester based adhesive agent (P) is shorter than the period of the cure treatment time of the epoxy based adhesive agent (E).

As clearly from FIG. 8, for example, at the cure temperature T1, the period of the cure treatment time of the polyester based adhesive agent (P) is Δ(t4−t3) longer than the period of the cure treatment time of the epoxy based adhesive agent (E). On the other hand, at the cure temperature T2, the period of the cure treatment time of the polyester based adhesive agent (P) is Δ(t2−t1) shorter than the period of the cure treatment time of the epoxy based adhesive agent (E).

Accordingly, in the semiconductor device according to the embodiment, the period of the cure time of the first adhesive agent 40 is set up shorter than the period of the cure time of the second adhesive agent 20. More specifically, as shown in FIG. 8 or FIG. 9, the epoxy based adhesive agent (E) and the polyester based adhesive agent (P) are combined to be selected as the first adhesive agent 40 and the second adhesive agent 20, respectively, so that the cure treatment can be performed at the temperature that the period of the cure treatment time of the epoxy based adhesive agent (E) becomes shorter than the period of the cure treatment time of the polyester based adhesive agent (P). Thus, according to the semiconductor device according to the embodiment, the cure treatment is performed at the temperature where the period of the cure time of the first adhesive agent 40 is set up shorter than the period of the cure time of the second adhesive agent 20, or the cure treatment is performed at the temperature where the period of the cure treatment time of the first adhesive agent 40 becomes shorter than the period of the cure treatment time of the second adhesive agent 20. Accordingly, since the first adhesive agent 40 coated on the inside of the bonded surface hardens earlier than the second adhesive agent 20 coated on the outside of the bonded surface hardens, the volatile gas occurred when the first adhesive agent 40 coated on the inside of the bonded surface hardens can be volatilized.

### (Modified Example 1 of Semiconductor Device)

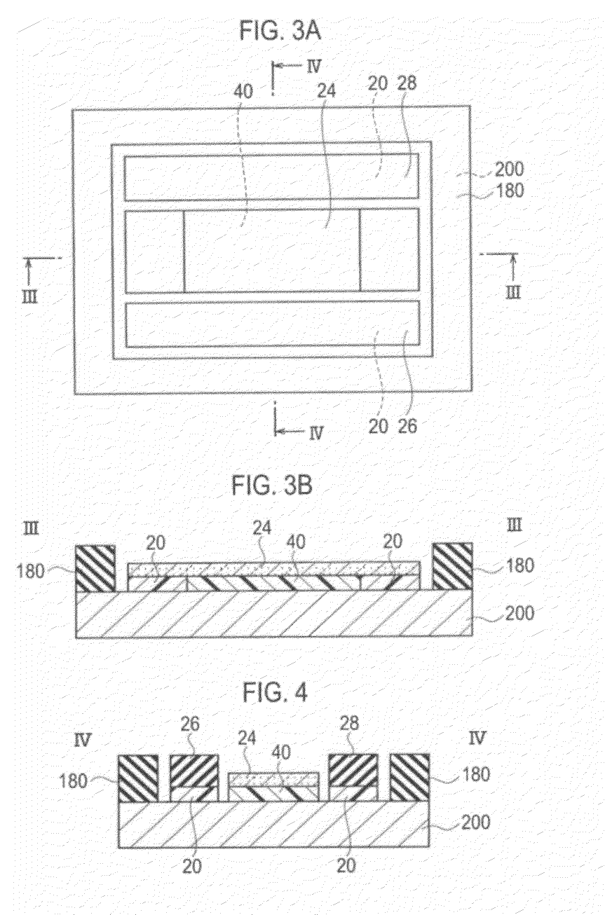

FIG. 3A shows a semiconductor device according to a modified example 1 of the embodiment, and is a schematic plan view in the case of applying Field Effect Transistor (FET) as a semiconductor chip, and FIG. 3B shows a schematic cross-sectional structure taken in the line line of FIG. 3A. Furthermore, FIG. 4 shows a schematic cross-sectional structure taken in the line IV-IV of FIG. 3A.

As shown in FIG. 3 to FIG. 4, the semiconductor device according to the modified example 1 of the embodiment is illustrated as the case where the semiconductor chip 24 mounted is not MMIC but FET. The semiconductor device according to the modified example 1 of the embodiment includes: a conductive base plate 200; a semiconductor chip 24 (e.g., FET substrate) bonded on the conductive base plate 200; and matching circuit substrates 26 and 28 bonded on the conductive base plate 200. Since a high degree of thermal dispersion effect is required for bonding the central part of the bonded surface between the semiconductor chip 24 and the conductive base plate 200, the central part of the bonded surface is bonded by the first adhesive agent 40 having the coefficient of thermal conductivity relatively higher than that of the second adhesive agent 20. On the other hand, since high bonding strength is required for bonding the peripheral part of the central part of the bonded surface between the semiconductor chip 24 and the conductive base plate 200, the peripheral part of the central part of the bonded surface is bonded by the second adhesive agent 20 having the bonding strength relatively higher than that of the first adhesive agent 40. Also, since a high bonding strength is required for bonding the respective bonded surfaces between the matching circuit substrates 26 and 28 and the conductive base plate 200, the respective bonded surfaces are bonded by the second adhesive agent 20 having the bonding strength relatively higher than that of the first adhesive agent 40.

Accordingly, since the semiconductor device according to the modified example 1 of the embodiment has the structure for bonding by using different adhesive agents (i.e., the adhesive agent excellent in the thermal dispersion characteristics and the adhesive agent excellent in the bonding strength) properly, it can achieve the semiconductor device excellent in the thermal dispersion characteristics and the bonding strength.

### (Coating Pattern of Adhesive Agent)

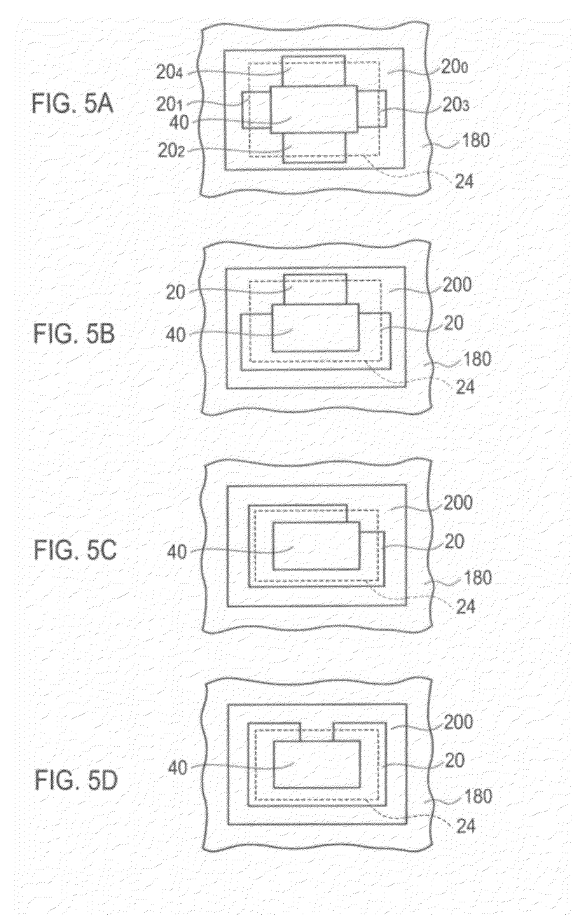

FIG. 5 is a schematic diagram showing an example of a coating variation between the first adhesive agent and the second adhesive agent in the semiconductor device according to a modified example 2 of the embodiment, and shows an aspect that the second adhesive agent 20 (20₁, 20₂, 20₃ and 20₄) is coated while forming apertures.

As shown in FIG. 5A, among four sides of the region coated by the first adhesive agent 40 coated on the bonded surface between the semiconductor chip 24 and the conductive base plate 200, the second adhesive agent 20₁ is coated on a part on the left of the left side as one faces the drawing, the second adhesive agent 20₂ is coated on a part below the lower side as one faces the drawing, the second adhesive agent 20₃ is coated on a part on the right of the right side as one faces the drawing, and the second adhesive agent 20₄ is coated on a part upon the upper side as one faces the drawing. That is, it has structure configured to skip the coating of the adhesive agent on four corners of the bonded surface between the semiconductor chip 24 and the conductive base plate 200, and the second adhesive agents 20₁, 20₂, 20₃ and 20₄ is coated so that apertures may be formed between the four corners of the region coated by the first adhesive agent 40 and the respective regions coated by the second adhesive agents 20₁, 20₂, 20₃ and 20₄.

In FIG. 5B, the second adhesive agent 20 is continuously coated over a part on the left of the left side, a whole region below the lower side, and a part on the right of the right side as one faces the drawing among the four sides of the region coated by the first adhesive agent 40 coated on the bonded surface between the semiconductor chip 24 and the conductive base plate 200, and the second adhesive agent 20 is coated on a part upon the upper side as one faces the drawing. That is, it has structure configured to skip the coating of the adhesive agent on the upper part as one faces the drawing of the bonded surface between the semiconductor chip 24 and the conductive base plate 200, and the second adhesive agent 20 is coated so that apertures maybe formed between the respective upper left-hand corner and upper right-hand corner of the region coated by the first adhesive agent 40, and the region coated by the second adhesive agent 20.

In FIG. 5C, the second adhesive agent 20 is continuously coated over a part upon the upper side, a whole region on the left of the left side, a whole region below the lower side, and a part on the right of the right side, as one faces the drawing, among the four sides of the region coated by the first adhesive agent 40 coated on the bonded surface between the semiconductor chip 24 and the conductive base plate 200. That is, it has structure configured to skip the coating of the adhesive agent on the upper right-hand corner as one faces the drawing of the bonded surface between the semiconductor chip 24 and the conductive base plate 200, and the second adhesive agent 20 is coated so that an aperture may be formed between the upper right-hand corner of the region coated by the first adhesive agent 40, and the region coated by the second adhesive agent 20.

In FIG. 5D, the second adhesive agent 20 is continuously coated over a part upon the upper side, a whole region on the left of the left side, a whole region below the lower side and a whole region on the right of the right side, as one faces the drawing, among the four sides of the region coated by the first adhesive agent 40 coated on the bonded surface between the semiconductor chip 24 and the conductive base plate 200. That is, it has structure configured to skip the coating of the adhesive agent on the upper parte as one faces the drawing of the bonded surface between the semiconductor chip 24 and the conductive base plate 200, and the second adhesive agent 20 is coated so that an aperture may be formed between the part upon the upper side of the region coated by the first adhesive agent 40, and the region coated by the second adhesive agent 20.

Thus, according to the semiconductor device according to the modified example 2 of the embodiment, the second adhesive agent 20 is coated so that the aperture(s) maybe formed between at least a part of region coated by the first adhesive agent 40, and the region coated by the second adhesive agent 20. Therefore the volatile gas occurred when the first adhesive agent 40 hardens can be volatilized from the aperture even if the second adhesive agent 20 (20₁, 20₂, 20₃ and 20₄) hardens earlier than the first adhesive agent 40 after the cure treatment (refer to FIG. 8).

Although the size of the aperture formed between at least a part of the region coated by the first adhesive agent 40 and the region coated by the second adhesive agent 20 is not particularly limited, an aperture required for volatilizing the volatile gas occurred when the first adhesive agent 40 hardens should just be formed, and an example of the size of the aperture is about 300 μm, for example.

The desired aperture can also be formed by coating the second adhesive agent 20 in a broken line shape, and therefore the volatile gas can be volatilized more effectively if the wavy-shaped aperture is combined with the coating pattern shown to FIG. 5.

### (Configuration Example of Semiconductor Device)

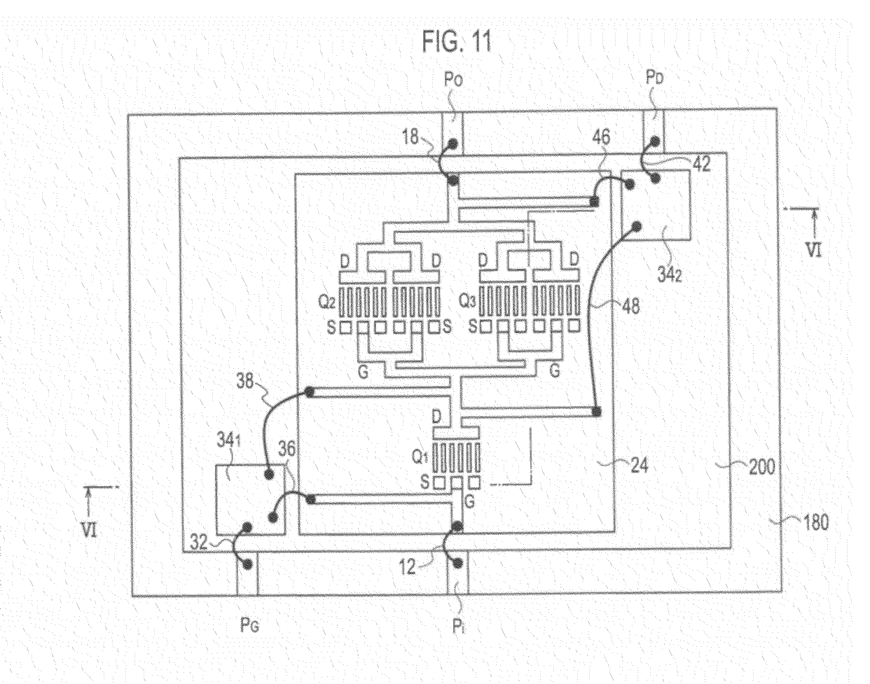

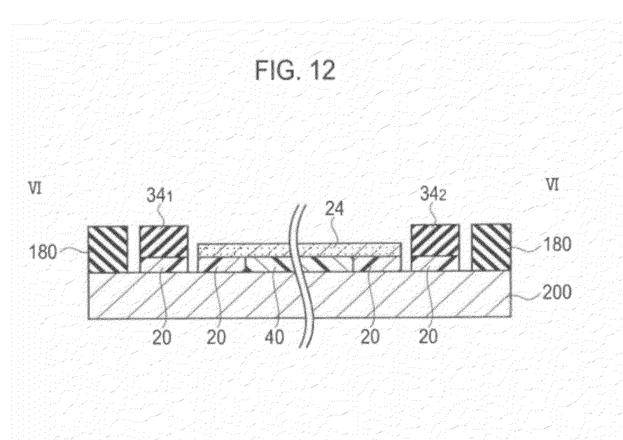

In the semiconductor device according to the embodiment, FIG. 11 shows a schematic planar pattern configuration showing an example which mounts the semiconductor chip 24 and other parts (e.g., capacitor substrates 34₁ and 34₂). Also, a schematic cross-sectional structure taken in the line VI-VI of FIG. 11 is expressed as shown in FIG. 12. However, the configuration example shown in FIG. 11 and FIG. 12 is only an example, and therefore, there are no limits to such the configuration.

The semiconductor device according to the embodiment includes: a conductive base plate 200; a semiconductor chip 24 bonded on the conductive base plate 200; capacitor substrates 34₁ and 34₂ disposed on the conductive base plate 200; a ceramic frame 180 disposed on the conductive base plate 200 to surround the semiconductor chip 24; an RF input terminal Pᵢ, an RF output terminal Pₒ, a drain bias terminal P_{D}, and a gate bias terminal P_{G} disposed on the ceramic frame 180; a bonding wire 12 for connecting between the RF input terminal Pᵢ and a gate terminal electrode G of a transistor Q₁; a bonding wire 32 for connecting between the gate bias terminal PG and the capacitor substrates 34₁; a bonding wire 36 for connecting between the capacitor substrate 34₁ and the gate terminal electrode G of the transistor Q₁; a bonding wire 38 for connecting between the capacitor substrate 34₁ and a gate terminal electrode G of transistors Q₂ and Q₃; a bonding wire 18 for connecting between a drain terminal electrode D of the transistors Q₂ and Q₃, and the RF output terminals Pₒ; a bonding wire 46 for connecting between the drain terminal electrode D of the transistors Q₂ and Q₃, and the capacitor substrates 34₂; a bonding wire 48 for connecting between a drain terminal electrode D of the transistor Q₁, and the capacitor substrates 34₂; and a bonding wire 42 for connecting between the capacitor substrate 34₂ and the drain bias terminal P_{D}.

In the semiconductor device according to the embodiment, input signal power is input into the transistor Q₁, and then the signal electric power amplified by the transistor Q₁ is distributed to be input into the respective transistors Q₂ and Q₃. Each signal electric power amplified by the transistors Q₂ and Q₃ is synthesized to be output electric power.

In the semiconductor device according to the embodiment, since a high degree of thermal dispersion effect is required for the central part of the bonded surface between the semiconductor chip 24 and the conductive base plate 200, the central part of the bonded surface is bonded by the first adhesive agent 40 having the coefficient of thermal conductivity relatively higher than that of the second adhesive agent 20. On the other hand, since high bonding strength is required for bonding the peripheral part of the central part of the bonded surface between the semiconductor chip 24 and the conductive base plate 200, the peripheral part of the central part of the bonded surface is bonded by the second adhesive agent 20 having the bonding strength relatively higher than that of the first adhesive agent 40. Also, since a high bonding strength is required for bonding the respective bonded surface between the capacitor substrates 34₁ and 34₂ and the conductive base plate 200, the respective bonded surface is bonded by the second adhesive agent 20 having the bonding strength higher than that of the first adhesive agent 40.

Accordingly, since the semiconductor device according to the embodiment has the structure for bonding by using different adhesive agents (i.e., the adhesive agent excellent in the thermal dispersion characteristics and the adhesive agent excellent in the bonding strength) properly, it can achieve the semiconductor device excellent in the thermal dispersion characteristics and the bonding strength.

### (Semiconductor Element Structure)

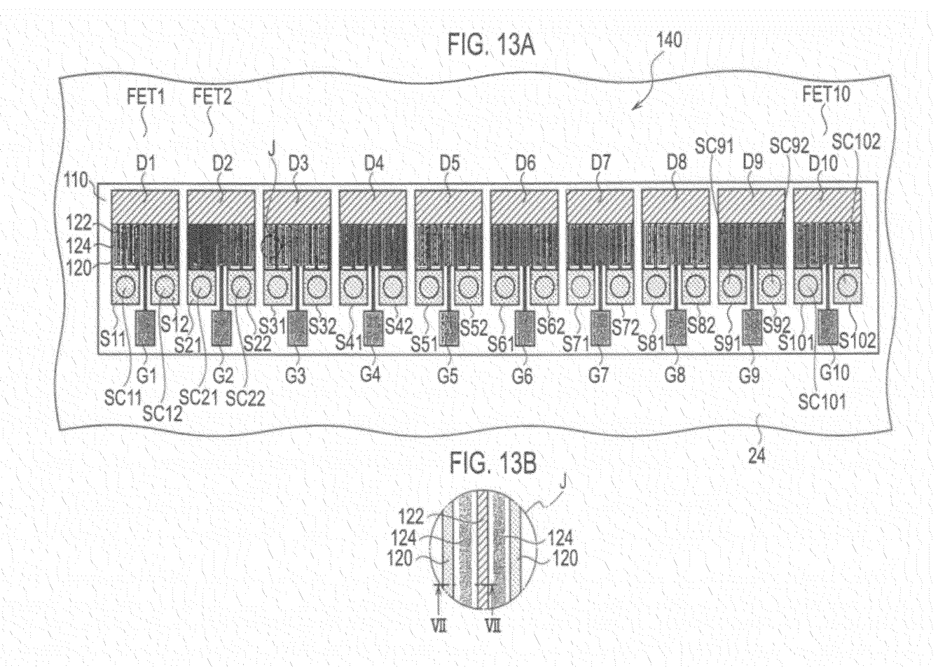

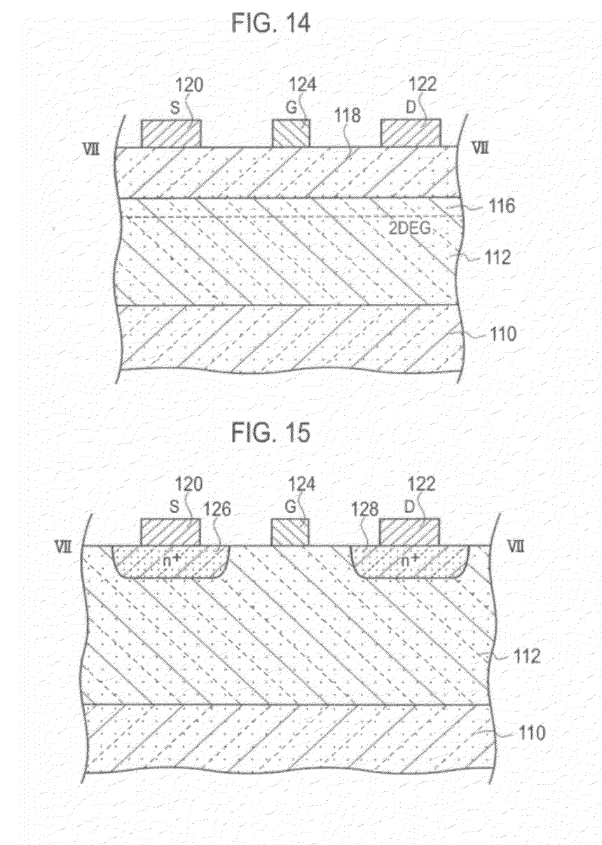

A schematic planar pattern configuration of an FET 140 of the semiconductor chip 24 mounted in the semiconductor device according to the embodiment is expressed as shown in FIG. 13A, and an enlarged drawing of J portion shown in FIG. 13A is expressed as shown in FIG. 13B. Also, schematic cross-sectional configurations, showing examples 1-4 of the FET 140 of the semiconductor chip 24 mounted in the semiconductor device according to the embodiment, taken in the line of FIG. 13B are expressed as shown in FIG. 14 to FIG. 17, respectively.

As shown in FIG. 14 to FIG. 17, in the semiconductor chip 24 mounted in the semiconductor device according to the embodiment, a plurality of FET cells FET1 to FET10 includes: a semi-insulating substrate 110; a gate finger electrode 124, a source finger electrode 120, and a drain finger electrode 122 which are disposed on a first surface of the semi-insulating substrate 110, and have a plurality of fingers, respectively; a plurality of gate terminal electrodes G1, G2, . . . , G10, a plurality of source terminal electrodes S11, S12, S21, S22, . . . , S101, and S102 and the drain terminal electrodes D1, D2, D10 which are disposed on the first surface of the semi-insulating substrate 110, and tie a plurality of fingers, respectively every the gate finger electrode 124, the source finger electrode 120, and the drain finger electrode 122; VIA holes SC11, SC12, SC21, SC22 , . . . , SC101, and SC102 disposed at the lower part of the source terminal electrodes 511, S12, S21, S22, . . . , S101, and S102; and a ground electrode (not shown) which is disposed on a second surface of the opposite side of a first surface of the semi-insulating substrate 110, and is connected via the VIA holes SC11, SC12, SC21, SC22, . . . , SC101, and SC102 to the source terminal electrodes S11, S12, S21, S22, . . . , S101, and S102.

The bonding wire 12 is connected to the gate terminal electrodes G1, G2, . . . , G10; the bonding wire 18 is connected to the drain terminal electrodes D1, D2, . . . , D10; the VIA holes SC11, SC12, SC21, SC22, . . . , SC101, and SC102 are formed in the lower part of the source terminal electrodes S11, S12, S21, S22, . . . , S101, and S102; the barrier metal layers (not shown) formed in the internal wall of the VIA holes SC11, SC12, SC21, SC22, . . . , SC101 and SC102; and the source terminal electrode S11, S12, S21, S22 , . . . , S101, and S102 formed on the barrier metal layers and connected to the ground electrode (not shown) via the filling metal layers (not shown) filled up with the VIA holes.

The semi-insulating substrate 110 is either of a GaAs substrate, an SiC substrate, a GaN substrate, a substrate in which a GaN epitaxial layer is formed on the SiC substrate, a substrate which a heterojunction epitaxial layer composed of GaN/AlGaN is formed on the SiC substrate, a sapphire substrate or a diamond substrate.

### (Constructional Example 1 of FET Cell)

As shown in FIG. 14, the configuration example 1 of the FET cell of the semiconductor chip 24 mounted in the semiconductor device according to the embodiment includes: a semi-insulating substrate 110; a nitride based compound semiconductor layer 112 disposed on the semi-insulating substrate 110; an aluminum gallium nitride layer (AlₓGa₁₋ₓN) (where 0.1<=x<=1) 118 disposed on the nitride based compound semiconductor layer 112; a source finger electrode (S) 120, a gate finger electrode (G) 124, and a drain finger electrode (D) 122 which are disposed on the aluminum gallium nitride layer (AlₓGa₁₋ₓN) (where 0.1<=x<=1) 118. A two dimensional electron gas (2DEG) layer 116 is formed in an interface between the nitride based compound semiconductor layer 112 and the aluminum gallium nitride layer(AlₓGa₁₋ₓN) (where 0.1<=x<=1) 118. A High Electron Mobility Transistor (HEMT) is illustrated in the constructional example 1 shown in FIG. 14.

### (Constructional Example 2 of FET Cell)

As shown in FIG. 15, the configuration example 2 of the FET cell of the semiconductor chip 24 mounted in the semiconductor device according to the embodiment includes: a semi-insulating substrate 110; a nitride based compound semiconductor layer 112 disposed on the semi-insulating substrate 110; a source region 126 and a drain region 128 which are disposed on the nitride based compound semiconductor layer 112; and a source finger electrode (S) 120 disposed on the source region 126, a gate finger electrode (G) 124 disposed on the nitride based compound semiconductor layer 112, and a drain finger electrode (D) 122 disposed on the drain region 128. Schottky contact is formed in the interface between the nitride based compound semiconductor layer 112 and the gate finger electrode (G) 124. MES FET (MESFET: Metal Semiconductor Field Effect Transistor) is illustrated in the constructional example 2 shown in FIG. 15.

### (Constructional Example 3 of FET Cell)

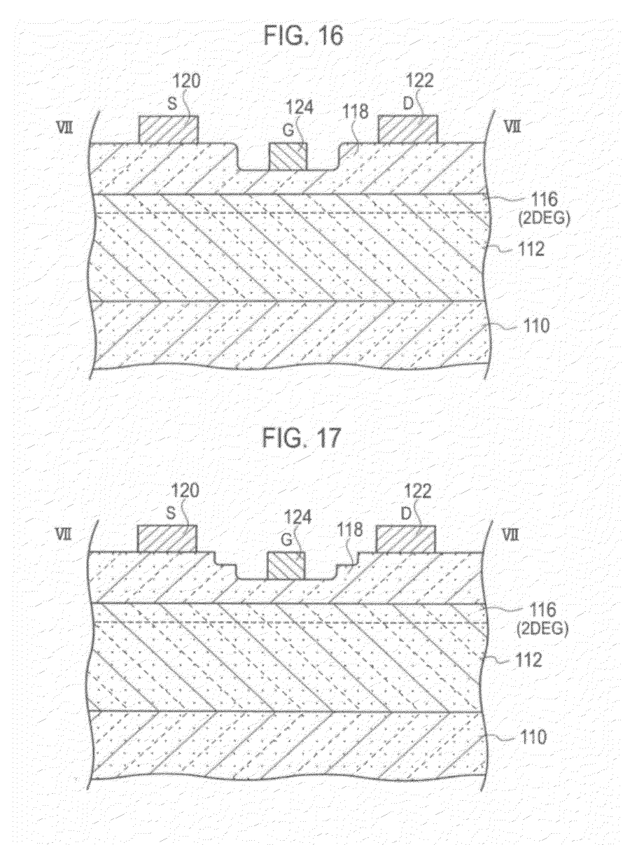

As shown in FIG. 16, the configuration example 3 of the FET cell of the semiconductor chip 24 mounted in the semiconductor device according to the embodiment includes: a semi-insulating substrate 110; a nitride based compound semiconductor layer 112 disposed on the semi-insulating substrate 110; an aluminum gallium nitride layer (AlₓGa₁₋ₓN) (where 0.1<=x<=1) 118 disposed on the nitride based compound semiconductor layer 112; a source finger electrode (S) 120 and a drain finger electrode (D) 122 which are disposed on the aluminum gallium nitride layer (AlₓGa₁₋ₓN) (where 0.1<=x<=1) 118;

and a gate finger electrode (G) 124 disposed at a recessed part on the aluminum gallium nitride layer (AlₓGa₁₋ₓN) (where 0.1<=x<=1) 118. A 2DEG layer 116 is formed in an interface between the nitride based compound semiconductor layer 112 and the aluminum gallium nitride layer (AlₓGa₁₋ₓN) (where 0.1<=x<=1) 118. HEMT is illustrated in the constructional example 3 shown in FIG. 16.

### (Constructional Example 4 of FET Cell)

As shown in FIG. 17, the configuration example 4 of the FET cell of the semiconductor chip 24 mounted in the semiconductor device according to the embodiment includes: a semi-insulating substrate 110; a nitride based compound semiconductor layer 112 disposed on the semi-insulating substrate 110; an aluminum gallium nitride layer (AlₓGa₁₋ₓN) (where 0.1<=x<=1) 118 disposed on the nitride based compound semiconductor layer 112; a source finger electrode (S) 120 and a drain finger electrode (D) 122 which are disposed on the aluminum gallium nitride layer (AlₓGa₁₋ₓN) (where 0.1<=x<=1) 118; and a gate finger electrode 124 disposed at a two-step recessed part on the aluminum gallium nitride layer (AlₓGa₁₋ₓN) (where 0.1<=x<=1) 118. A 2DEG layer 116 is formed in an interface between the nitride based compound semiconductor layer 112 and the aluminum gallium nitride layer (AlₓGa₁₋ₓN) (where 0.1<=x<=1) 118. HEMT is illustrated in the constructional example 4 shown in FIG. 17.

Moreover, in the above-mentioned constructional examples 1-4, the nitride based compound semiconductor layer 112 except an active area is electrically used as an inactivity isolation region. In this case, the active area is composed of: the source finger electrode 120; the 2DEG layer 116 directly under the gate finger electrode 124 and the drain finger electrode 122; and the 2DEG layer 116 between the source finger electrode 120 and the gate finger electrode 124 and between the drain finger electrode 122 and the gate finger electrode 124.

As another fabrication method of the isolation region, it can also be formed by ion implantation into the aluminum gallium nitride layer (AlₓGa₁₋ₓN) (where 0.1<=x<=1) 118 and a part of the nitride based compound semiconductor layer 112 in depth direction. As ion species, nitrogen (N), argon (Ar), etc. are applicable, for example. Moreover, the amount of dosage with the ion implantation is about 1×10¹⁴ (ions/cm²), for example, and accelerating energy is about 100 keV to 200 keV, for example. An insulating layer for passivation (not shown) is formed on the isolation region and the device surface. As the insulating layer, it can be formed of a nitride film, an alumina (Al₂O₃) film, an oxide film (SiO₂), an oxynitriding film (SiON) , etc. deposited by a Plasma Enhanced Chemical Vapor Deposition (PECVD) method, for example.

The source finger electrode 120 and the drain finger electrode 122 are formed of Ti/Al etc., for example. The gate finger electrode 124 can be formed, for example of Ni/Au etc.

In addition, in the semiconductor device 24 according to the first embodiment, the pattern length of longitudinal direction of the gate finger electrode 124, the source finger electrode 120, and the drain finger electrode 122 is set up to be shorter as operating frequency becomes higher. For example, in the millimeter wave band, the pattern length is about 25 μm to 50 μm.

Also, the width of the source finger electrode 120 is about 40 μm, for example, and the width of the source terminal electrode S11, S12, S21, S22, . . . , S101, and S102 is about 100 μm, for example. Yet also, the formation width of the VIA holes SC11, SC12, SC21, SC22, . . . , SC101, and SC102 is about 10 μm to about 40 μm, for example.

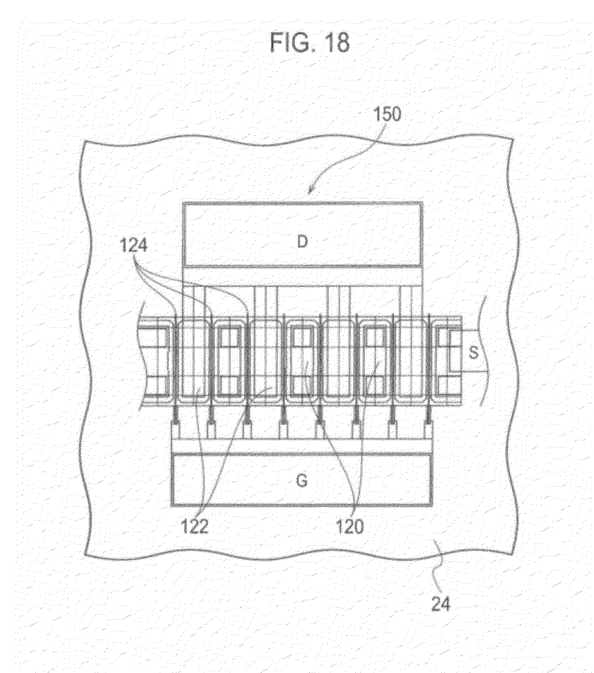

As shown in FIG. 18, a schematic planar pattern configuration showing alternative FET 150 of the semiconductor chip 24 mounted in the semiconductor device according to the embodiment includes: a gate finger electrode 124, a source finger electrode 120, and a drain finger electrode 122 disposed on a semi-insulating substrate and having a plurality of fingers, respectively; a gate terminal electrode G and a drain terminal electrode D disposed on the semi-insulating substrate and tying a plurality of fingers, respectively, every gate finger electrode 124 and drain finger electrode 122; and a source terminal electrode S which disposed on the semi-insulating substrate and connected to a plurality of fingers of the source finger electrode 120 with overlay electric contact, respectively.

According to the embodiment described above, it can achieve the semiconductor device having the structure for bonding by using different adhesive agents (i.e., the adhesive agent excellent in the thermal dispersion characteristics and the adhesive agent excellent in the bonding strength) properly.

### [Other Embodiments]

While a certain the semiconductor device according to the embodiment has been described, the embodiment has been presented by way of examples only, and is not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

It needless to say that not only the FET but a High Electron Mobility Transistor (HEMT) or amplifying elements, such as a Laterally Diffused Metal-Oxide-Semiconductor Field Effect Transistor (LDMOS) and a Hetero-junction Bipolar Transistor (HBT), etc. can be applied as the semiconductor device according to the embodiment.

Such being the case, the present invention covers a variety of embodiments, whether described or not.

What is claimed is:

1. A semiconductor device comprising:
a conductive base plate;
a semiconductor chip bonded on the conductive base plate;
a first adhesive agent disposed on a central part of a bonded surface between the semiconductor chip and the conductive base plate; and
a second adhesive agent disposed on a peripheral part of the central part of the bonded surface between the semiconductor chip and the conductive base plate, wherein
a coefficient of thermal conductivity of the first adhesive agent is relatively higher than that of the second adhesive agent, and a bonding strength of the second adhesive agent is relatively higher than that of the first adhesive agent.

2. The semiconductor device according to claim 1, wherein a period of cure time of the first adhesive agent is shorter than a period of cure time of the second adhesive agent.

3. The semiconductor device according to claim 1, wherein
a cure treatment is performed at a temperature where a period of the cure treatment time of the first adhesive agent is shorter than a period of a cure treatment time of the second adhesive agent, and then the semiconductor chip and the conductive base plate are bonded.

4. The semiconductor device according to claim 1, wherein
the second adhesive agent is not coated on a portion of periphery of the semiconductor chip among the bonded surface between the semiconductor chip and the conductive base plate.

5. The semiconductor device according to claim 1, wherein
the second adhesive agent is coated so that a predetermined aperture is formed between at least a part of a region coated by the first adhesive agent and a region coated by the second adhesive agent.

6. The semiconductor device according to claim 1, wherein
the first adhesive agent is an epoxy resin based adhesive agent, and the second adhesive agent is a polyester based adhesive agent.

7. The semiconductor device according to claim 1, wherein
the first adhesive agent is an adhesive agent composed of epoxy resin based organic materials including Ag as a conductive filler, and the second adhesive agent is an adhesive agent composed of polyester based polymeric materials including Ag as a conductive filler.

8. The semiconductor device according to claim 1 further comprising
a circuit substrate disposed on the conductive base plate, wherein
a bonded surface between the circuit substrate and the conductive base plate is bonded by the second adhesive agent.

9. The semiconductor device according to claim 8, wherein
the circuit substrate is a substrate selected from the group consisting of a matching circuit substrate and a capacitor substrate.

10. The semiconductor device according to claim 1, wherein
the semiconductor chip comprises:
a substrate;
a gate finger electrode, a source finger electrode, and a drain finger electrode disposed on a first surface of the substrate and having a plurality of fingers, respectively;
a plurality of gate terminal electrodes, a plurality of source terminal electrodes, and a drain terminal electrode disposed on the first surface of the substrate and tying a plurality of fingers, respectively for every the gate finger electrode, the source finger electrode, and the drain finger electrode;
a VIA hole disposed at an under part of the source terminal electrode; and
a ground electrode disposed on a second surface of an opposite side of the first surface of the substrate, and connected to the source terminal electrode via the VIA hole.

11. The semiconductor device according to claim 1, wherein
the semiconductor chip comprises:
a substrate;
a gate finger electrode, a source finger electrode, and a drain finger electrode disposed on the substrate and having a plurality of fingers, respectively;
a gate terminal electrode and a drain terminal electrode disposed on the substrate and tying a plurality of fingers, respectively for every gate finger electrode and drain finger electrode; and
a source terminal electrode disposed on the substrate and connected to a plurality of fingers of the source finger electrode 120 with overlay electric contact, respectively.

12. The semiconductor device according to claim 10, wherein
the substrate is a substrate selected from the group consisting of an SiC substrate, a GaAs substrate, a GaN substrate, a substrates in which a GaN epitaxial layer is formed on an SiC substrate, a substrate in which the GaN epitaxial layer is formed on the Si substrate, a substrate in which the heterojunction epitaxial layer composed of GaN/AlGaN is formed on the SiC substrate, a substrate in which the GaN epitaxial layer is formed on the sapphire substrate, a sapphire substrate or a diamond substrate, and a semi-insulating substrate.

13. The semiconductor device according to claim 11, wherein
the substrate is a substrate selected from the group consisting of an SiC substrate, a GaAs substrate, a GaN substrate, a substrates in which a GaN epitaxial layer is formed on an SiC substrate, a substrate in which the GaN epitaxial layer is formed on the Si substrate, a substrate in which the heterojunction epitaxial layer composed of GaN/AlGaN is formed on the SiC substrate, a substrate in which the GaN epitaxial layer is formed on the sapphire substrate, a sapphire substrate or a diamond substrate, and a semi-insulating substrate.

14. A fabrication method for a semiconductor device comprising:
forming a first adhesive agent on a central part of a bonded surface between a semiconductor chip and a conductive base plate;
forming a second adhesive agent on a peripheral part of the central part of the bonded surface between the semiconductor chip and the conductive base plate;
mounting the semiconductor chip on the first adhesive agent and the second adhesive agent disposed on the conductive base plate; and
subjecting the first adhesive agent and the second adhesive agent to a cure treatment to be hardened, wherein
a coefficient of thermal conductivity of the first adhesive agent is relatively higher than that of the second adhesive agent, and a bonding strength of the second adhesive agent is relatively higher than that of the first adhesive agent.

15. The fabrication method for the semiconductor device according to claim 14, wherein
a period of cure time of the first adhesive agent is shorter than a period of cure time of the second adhesive agent.

16. The fabrication method for the semiconductor device according to claim 14, wherein
a cure treatment is performed at a temperature where a period of the cure treatment time of the first adhesive agent is shorter than a period of a cure treatment time of the second adhesive agent, and then the semiconductor chip and the conductive base plate are bonded.
